(19) United States
(12) Patent Application Publication
(10) Pub. No.: US 2007/0285990 A1
(43) Pub. Date: Dec. 13, 2007

(54) Semiconductor device and method for compensating voltage drop of a bit line

(75) Inventor: Seung-Won Lee, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/648,293

(22) Filed: Dec. 29, 2006

(30) Foreign Application Priority Data
Jun. 10, 2006 (KR) 10-2006-0052259

(51) Int. Cl. G11C 11/34

(52) U.S. Cl. 365/185.25

(57) ABSTRACT

Provided are a semiconductor device and a method for compensating for a voltage drop of a bit line. The semiconductor device includes at least one monitoring bit line and at least one main memory bit line, and monitors a voltage of the at least one monitoring bit line after a precharging operation and supplies a predetermined compensation current to the at least one monitoring bit line and the at least one main memory bit line based on a monitoring result. Accordingly, it is possible to precisely compensate for a voltage drop occurring in the main memory bit line due to under precharge or leakage current, thereby preventing unnecessary compensation current from being supplied. Therefore, it is possible to stably perform a read operation of the semiconductor device.

### CROSS-REFERENCE TO RELATED PATENT APPLICATIONS

This application claims priority under 35 U.S.C. §119 to Korean Patent Application No. 10-2006-0052259, filed on Jun. 10, 2006, the disclosure of which is incorporated by reference herein.

### BACKGROUND OF THE INVENTION

1. Technical Field

The present disclosure relates to a semiconductor device, and more particularly, to a semiconductor device capable of compensating for a voltage drop of a bit line.

2. Discussion of the Related Art

During a read operation, a sense amplifier of a floating gate memory device, such as a flash memory device, may generally precharge a bit line connected to a memory cell. A voltage drop of the bit line may then be sensed according to the flow of current through the selected memory cell to determine whether the selected memory cell is in an “on” state or an “off” state.

In particular, a single-ended type sense amplifier precharges a bit line connected to a memory cell to be sensed to a predetermined precharge voltage during a precharging operation. A voltage of a detection node connected to the bit line is compared with a predetermined voltage during a sensing operation. It is determined whether the memory cell is in the “on” state or the “off” state according to the comparison result.

For example, when the bit line is precharged to the predetermined precharge voltage and the selected memory cell is in an erase state or the “on” state, electric charges in the bit line is discharged to ground via the selected memory cell, thereby lowering the voltage of the bit line. The voltage drop of the bit line causes a voltage drop of the detection node that senses the voltage of the bit line. Thus, the sense amplifier senses and amplifies the voltage of the detection node to perceive that the memory cell connected to the bit line is in the “on” state or the erasure state.

However, when the bit line is precharged to the predetermined precharge voltage and the selected memory cell is in a program state or the “off” state, electric charges in the bit line is not discharged to ground via the selected memory cell, and thus, the voltage of the bit line is maintained at the predetermined precharge voltage. Accordingly, the voltage of the detection node is maintained at the precharge voltage, and thus, the sense amplifier perceives that the memory cell is in the “off” state or the program state.

Because it may take a long time to precharge the bit line to the predetermined precharge voltage during the precharging operation, the bit line may be precharged to a voltage lower than the predetermined precharge voltage. This condition is referred to as “under precharge”. Thus, the bit line can be maintained in a under precharge state, depending on the amount of time given for the precharge.

When the selected memory cell of a main memory cell array is in the “off” state, the voltage of the bit line connected to the memory cell may be lowered due to leakage current flowing through the memory cell. Thus, the sense amplifier may perceive that a state of a memory cell is in the “on” state even when the memory cell is substantially in the “off” state.

Accordingly, as illustrated in FIG. 1, predetermined compensation current may be supplied to a detection node to compensate for under precharge of the bit line or a voltage drop of the bit line due to leakage current.

FIG. 1 is a block diagram of a conventional semiconductor device 10 that includes a sense amplifier 14 having a compensation current supply circuit. Referring to FIG. 1, the conventional semiconductor device 10 includes a main memory cell array 12 and a sense amplifier 14.

The main memory cell array 12 includes a plurality of bit lines 20, . . . , 30, a plurality of word lines WL[0], WL[1], . . . , WL[n], and a plurality of floating gate transistors 21, 22, . . . , 2n, 31, 32, . . . , 3n that are connected between the bit lines 20, . . . , 30 and the word lines WL[0], WL[1], . . . , WL[n], respectively. Where n is a natural number (zero or a positive integer). Each of the floating gate transistors 21, 22, . . . , 2n, 31, 32, . . . 3n acts as a memory cell that stores predetermined data.

The sense amplifier 14 senses and amplifies data from a memory cell (for example, a floating gate transistor) by selecting a word line and a bit line. The word line of the main memory cell array 12 is selected based on a selection signals from a row address decoder (not shown). The bit line of the main memory cell array 12 is selected based on selection signals Y_path from a column address decoder (not shown).

The sense amplifier 14 includes a precharging circuit 16, a compensation current supply circuit 18, and a plurality of output buffers 20-1, . . . , 20-2.

The precharging circuit 16 supplies a predetermined current I_pre to the bit lines 20 and 30 connected to the corresponding memory cells 21, 22, . . . , 2n, 31, 32, . . . , 3n to precharge the bit lines 20 and 30, based on a precharge control signal nPRE having a logical low level (“0”).

The compensation current supply circuit 18 supplies compensation current I_load to detection nodes S1, . . . , S2, based on a control signal nLoad having a logical low level (“0”) The output buffers 20-1, . . . , 20-2 buffer the voltages of the detection nodes S1, . . . , S2 and output buffered signals, respectively.

However, the compensation current supply circuit 18 supplies the compensation current I_load to the detection nodes S1, . . . , S2 without recognizing an amount of voltage to which each of the detection nodes S1, . . . , S2 is precharged, or an amount of leakage current flowing through a selected or unselected memory cell. Accordingly, compensation current I_load may be unnecessarily supplied to the sense amplifier 14.

### SUMMARY OF THE INVENTION

The present disclosure describes a semiconductor device and method for compensating for under precharge of a bit line and/or leakage current flowing through a memory cell.

According to one exemplary embodiment of the present invention, there is provided a semiconductor device comprising a first monitoring bit line connected to at least one first memory cell having a source, a drain, a floating gate, a control gate, and a substrate. A first bit line is connected to at least one second memory cell having a source, a drain, a floating gate, a control gate, and a substrate. A precharging circuit precharges a second monitoring bit line and a second bit line to a predetermined voltage in response to a precharge control signal. A compensation current supply circuit senses a voltage of the second monitoring bit line and supplies a predetermined current to the second monitoring bit line and the second bit line based on a sensing result. A buffer buffers current flowing through the second bit line, based on a state of the at least one second memory cell connected to the first bit line. A switching circuit controls a connection of the first monitoring bit line to the second monitoring bit line and a connection of the first bit line to the second bit line, in response to at least one corresponding control signal.

The drain of the at least one first memory cell is connected to the first monitoring bit line, and the source of the at least one first memory cell is in a floating state. The drain of the at least one second memory cell is connected to the first bit line. The source of the at least one second memory cell is connected to ground. The control gate of the at least one first memory cell and the control gate of the at least one second memory cell are respectively connected to corresponding word lines.

Also, the drain of the at least one first memory cell is connected to the first monitoring bit line. The source and the control gate of the at least one first memory cell are connected to ground. The drain of the at least one second memory cell is connected to the first bit line. The source of the at least one second memory cell is connected to ground. The control gate of the at least one second memory cell is connected to a word line. The at least one first memory cell is in a program state.

The compensation current supply circuit is a current mirror and senses a voltage of the second monitoring bit line and mirrors the predetermined current flowing through the second monitoring bit line to the second bit line based on the sensed result.

According to another exemplary embodiment of the present invention, there is provided a semiconductor device comprising at least one monitoring bit line connected to a drain of each of a plurality of first floating gate transistors. At least one bit line is connected to a drain of each of a plurality of second floating gate transistors. A compensation current supply circuit monitors a voltage of the at least one monitoring bit line after a precharging operation and supplies a predetermined compensation current to the at least one monitoring bit line and the at least one bit line based on a monitoring result.

According to another exemplary embodiment of the present invention, there is provided a semiconductor device comprising at least one monitoring bit line. There are a plurality of bit lines. There is a detection node. There are a plurality of main detection nodes. A precharging circuit supplies a predetermined precharge voltage to the detection node and the main detection nodes in response to a precharge control signal. At least one first transistor connects the detection node and the at least one monitoring bit line in response to at least one first control signal. At least one second transistor respectively connects the bit lines and the main detection nodes in response to at least one second control signal. A compensation current supply circuit supplies compensation current to the detection node and the main detection nodes based on a voltage of the detection node. A plurality of buffers each sense and buffer a voltage of a corresponding node of the main detection nodes. The at least one monitoring bit line is connected to each drain of a plurality of first floating gate transistors. The bit lines are respectively connected to drains of a plurality of second floating gate transistors.

A source of each of the first floating gate transistors is in a floating state. A control gate of each of the first floating gate transistors and a control gate of each of the second floating gate transistors are connected to a corresponding word line of a plurality of word lines.

A gate and a source of each of the first floating gate transistors are connected to ground. A gate of each of the second floating gate transistors is connected to a corresponding word line of a plurality of word lines. A source of each of the second floating gate transistors is connected to ground. Each of the first floating gate transistors is in a program state.

The compensation current supply circuit is formed as a current mirror. A plurality of output terminals of the current mirror are respectively connected to the main detection nodes. The compensation current mirrored by the current mirror is supplied to the main detection nodes.

The first floating gate transistors and the second floating gate transistors are embodied in a main memory cell array. A total number of the first floating gate transistors is equal to a total number of the second floating gate transistors.

According to another aspect of the present invention, there is provided a method of compensating for a voltage drop of at least one bit line after a precharging operation in a semiconductor device. The semiconductor device has at least one monitoring bit line connected to each drain of a plurality of first floating gate transistors and the at least one bit line connected to each drain of a plurality of second floating gate transistors. The method comprises monitoring a voltage of the at least one monitoring bit line. A predetermined compensation current is supplied to the at least one monitoring bit line and the at least one bit line based on a monitoring result.

The method further includes maintaining each of the first floating gate transistors in an off state.

### BRIEF DESCRIPTION OF THE DRAWINGS

The above and other aspects of exemplary embodiments of the present invention will become more apparent by describing in detail exemplary embodiments thereof with reference to the attached drawings in which:

FIG. 1 is a block diagram of a conventional semiconductor device that includes a sense amplifier having a compensation current supply circuit;

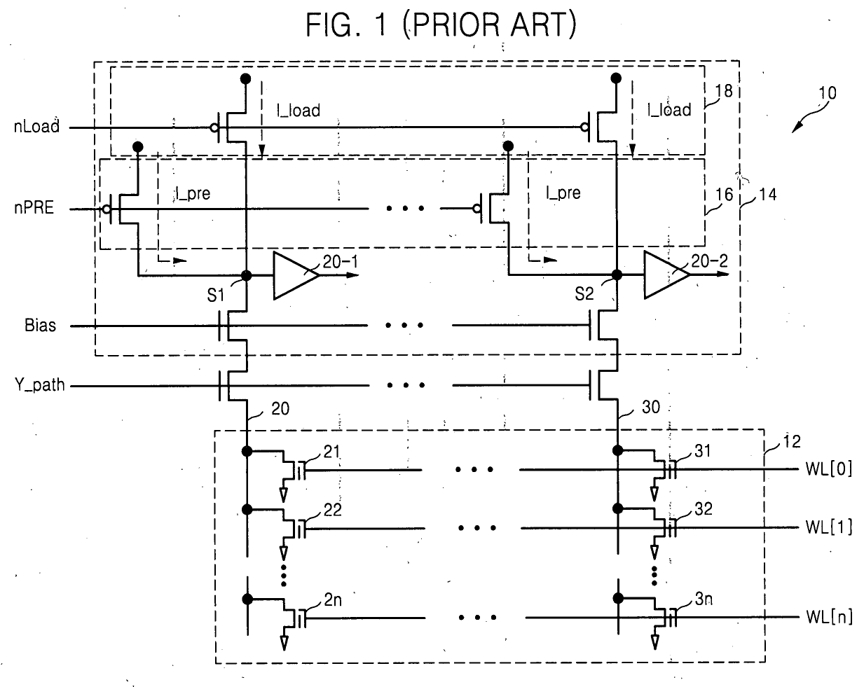

FIG. 2 is a functional block diagram of a semiconductor device having a sense amplifier and a main memory cell array according to some embodiments of the present invention;

FIG. 3 is a block diagram of a semiconductor device that includes a sense amplifier having a compensation current supply circuit and a main memory cell array according to some embodiments of the present invention;

FIG. 4 is a block diagram of a semiconductor device that includes a sense amplifier having a compensation current supply circuit and a main memory cell array according to some embodiments of the present invention;

FIG. 5 is a timing diagram of a sense amplifier having a compensation current supply circuit according to some embodiments of the present invention; and

FIG. 6 is a flowchart illustrating a method of compensating for a voltage drop of a bit line according to some embodiments of the present invention.

### DETAILED DESCRIPTION OF EXEMPLARY EMBODIMENTS

Hereinafter, exemplary embodiments of the present invention will be described in detail with reference to the accompanying drawings. Like reference numerals denote like elements throughout the drawings.

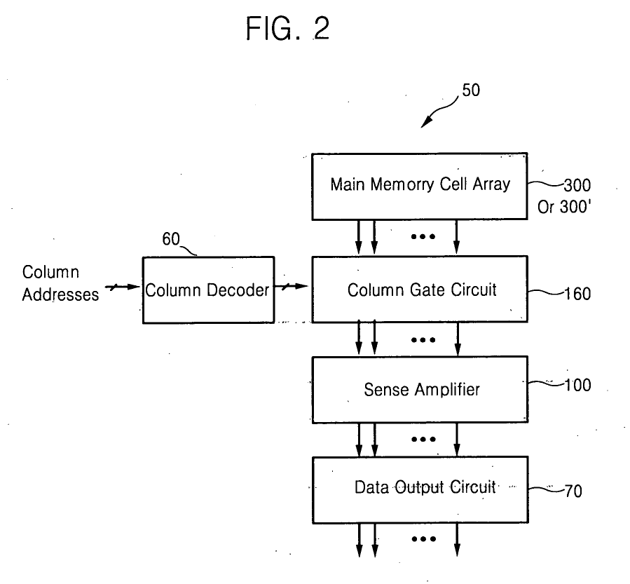

FIG. 2 is a functional block diagram of a semiconductor device 50 having a sense amplifier 100 and a main memory cell array 300 (or 300′) according to some exemplary embodiments of the present invention. Referring to FIG. 2, the semiconductor device 50 includes a column decoder 60, a data output circuit 70, the sense amplifier 100, a column gate circuit 160, and the main memory cell array 300 (or 300′).

The main memory cell array 300 (or 300′) stores data therein. The column decoder 60 receives column addresses and generates selection signals. The column gate circuit 160 selects at least one bit line from among a plurality of bit lines of the main memory cell array 300 (or 300′) in response to the selection signals received from the column decoder 60, and connects the selected at least one bit line to the sense amplifier 100. The sense amplifier 100 senses and amplifies data from a memory cell connected to the selected at least one bit line. The data sensed by the sense amplifier 100 is output via the data output circuit 70.

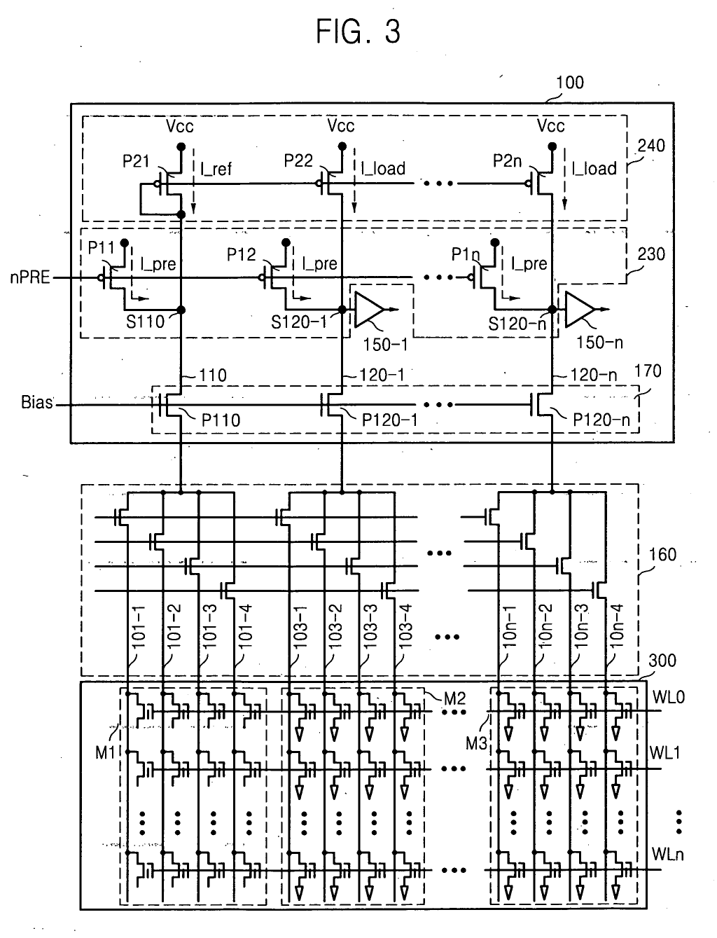

FIG. 3 is a block diagram of a semiconductor device that includes a sense amplifier 100 having a compensation current supply circuit 240, and a main memory cell array 300 according to some exemplary embodiments of the present invention. Referring to FIGS. 2 and 3, the sense amplifier 100 includes a detection node S110, a plurality of main detection nodes S120-1, . . . , S120-n, a precharging circuit 230, the compensation current supply circuit 240, and a plurality of buffers 150-1, . . . , 150-n. The detection node S110 is present on a monitoring bit line 110.

The sense amplifier 100 may further include a bias current supply circuit 170 to supply bias current in response to a bias control signal Bias. The bias current supply circuit 170 includes a plurality of MOS transistors P110, P120-1, . . . , P120-n. During a precharging operation, the precharging circuit 230 supplies a predetermined current I_pre to the detection node S110 and the main detection nodes S120-1, . . . , S120-n to precharge them to a predetermined precharge voltage, e.g., supply voltage Vcc, in response to a precharge control signal nPRE having a low level.

The precharging circuit 230 includes a plurality of PMOS transistors P11, P12, . . . , P1n, and precharges the detection node S110 and the main detection nodes S120-1, . . . , S120-n to the predetermined precharge voltage in response to a precharge control signal. nPRE that becomes low during the precharging operation. The detection node S110 is connected to the monitoring bit line 110, and the main detection nodes S120-1, . . . , S120-n are connected to a plurality of bit lines 120-1, . . . , 120-n, respectively.

After the precharging operation, the compensation current supply circuit 240 supplies compensation current I_ref to the detection node S110 based on the voltage of the detection node S110, and at the same time, supplies mirrored compensation current I_load to the main detection nodes S120-1, . . . , S120-n, respectively.

The compensation current supply circuit 240 may be embodied as a current mirror having a plurality of PMOS transistors P21, P22, . . . , P2n. Accordingly, the compensation current supply circuit 240 can supply the compensation current I_ref to the detection node S110, and the mirrored compensation current I_load to the main detection nodes S120-1, . . . , S120-n, respectively. For example, the output terminals of the compensation current supply circuit 240 are connected to the main detection nodes S120-1, . . . , S120-n, respectively.

Each of the buffer 150-1, . . . , 150-n senses and amplifies (or buffers) a voltage of a corresponding detection node of the main detection nodes S120-1, . . . , S120-n. For example, each of the buffers 150-1, . . . , 150-n buffers current flowing through the corresponding main detection node S120-1, . . . , or S120-n, based on a state of at least one memory cell connected to each of the plurality of bit lines 103-1, 103-2, 103-3, 103-4, . . . , 10n-1, 10n-2, 10n-3, or 10n-4.

The column gate circuit 160 connects at least one of monitoring bit lines 101-1, 101-2, 101-3, and 101-4 and at least one of the bit lines 103-1, 103-2, 103-3, 103-4, . . . , 10n-1, 10n-2, 10n-3, and 10n-4 to at least one of the bit lines 110, 120-1, . . . , 120-n of the sense amplifier 100, in response to the selection signals from the column decoder 60 illustrated in FIG. 2. The column gate circuit 160 may be embodied as a plurality of MOS transistors.

Here, the column gate circuit 160 and the bias current supply circuit 170 form a switching circuit for connecting the sense amplifier 100 to the main memory cell array 300. Thus, the switching circuit is capable of connecting the detection node S110 of the sense amplifier 100 and at least one of the monitoring bit lines 101-1, 101-2, 101-3, and 101-4, based on a bias control signal Bias and the selection signals from the column decoder 60.

Also, the switching circuit is capable of respectively connecting the main detection nodes S120-1, . . . , S120-n of the sense amplifier 100 and the bit lines 103-1, 103-2, 103-3, 103-4, . . . , 10n-1, 10n-2, 10n-3, and 10n-4 of the main memory cell array 300, based on the bias control signal Bias and the selection signals from the column decoder 60.

The main memory cell array 300 includes the one or more monitoring bit lines 101-1, 101-2, 101-3, and 101-4, a plurality of the bit lines 103-1, 103-2, 103-3, 103-4, . . . , 10n-1, 10n-2, 10n-3, and 10n-4, and a plurality of word lines WL0, WL1 through WLn.

Each drain of a plurality of first floating gate transistors M1, for example, is connected to the corresponding monitoring bit line 101-1, 101-2, 101-3, and 101-4. Each control gate of the first floating gate transistors M1 is connected to a corresponding word line of the plurality of the word lines WL0, WL1 through WLn. Each source of the plurality of first floating gate transistors M1 is maintained in a floating state.

Each of the first floating gate transistors M1 may be embodied as a flash memory having a drain, a source, a floating gate, a control gate, and a substrate. Also, each of the first floating gate transistors M1 may be embodied as EPROM or EEPROM, and may act as a memory cell.

Each drain of a plurality of second floating gate transistors M2 and M3, for example, is connected to a corresponding bit line 103-1, 103-2, 103-3, 103-4, . . . , 10n-1, 10n-2, 10n-3, and 10n-4. Also, each control gate of the second floating gate transistors M2 and M3 is connected to the corresponding word line WL0, WL1 through WLn, and each source of the plurality of second floating gate transistors M2 and M3 is connected to ground.

The characteristics of the first floating gate transistors M1 are preferably the same as those of the second floating gate transistors M2 and M3 to monitor the characteristics of the second floating gate transistors M2 and M3.

Also, the characteristics of the monitoring bit lines 101-1, 101-2, 101-3, and 101-4 are preferably the same as those of the bit lines 103-1, 103-2, 103-3, 103-4, . . . , 10n-1, 10n-2, 10n-3, and 10n-4 to monitor the characteristics of the bit lines 103-1, 103-2, 103-3, 103-4, . . . , 10n-1, 10n-2, 10n-3, and 10n-4.

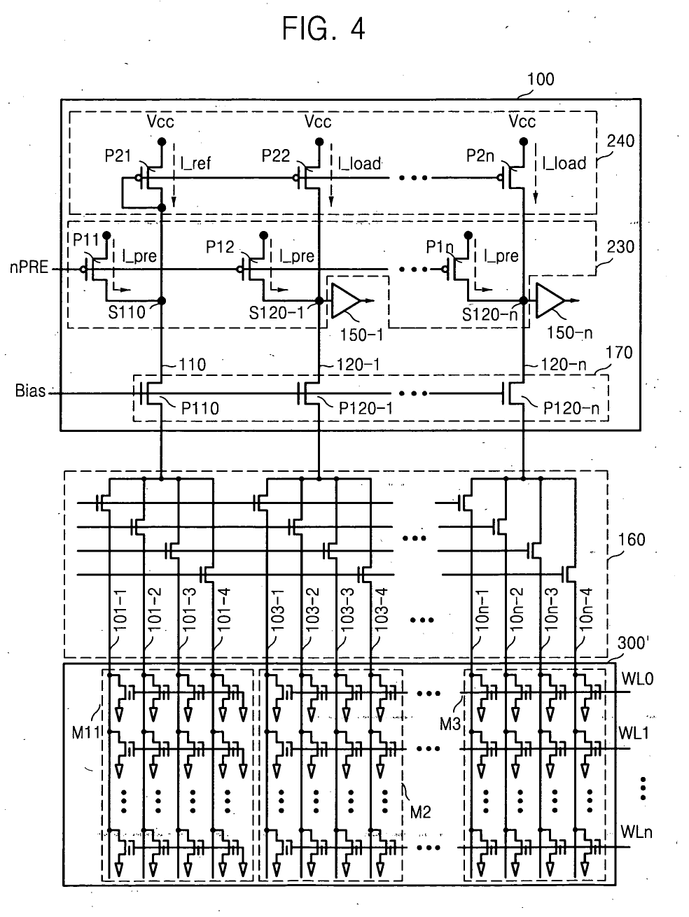

FIG. 4 is a block diagram of a semiconductor device that includes a sense amplifier 100 having a compensation current supply circuit 240, and a main memory cell array 300′ according to some exemplary embodiments of the present invention. Referring to FIGS. 3 and 4, each drain of a plurality of first floating gate transistors M 1 is connected to a corresponding monitoring bit line 101-1, 101-2, 101-3, and 101-4, and each control gate and source of the first floating gate transistors M11 are connected to ground.

As illustrated in FIGS. 3 and 4, each of the first floating gate transistors (or, flash memory cells) M1 or M11 connected to the monitoring bit line 101-1 is maintained in the “off” state. That is, each of the flash memory cells M1 or M11 is programmed, each gate of the flash memory cells M1 or M11 is connected to ground, or each source of the flash memory cells M1 or M11 is maintained in the floating state. Accordingly, current does not flow from at least one of the monitoring bit lines 101-1, 101-2, 101-3, and 101-4 to ground via each of the flash memory cells M1 or M11.

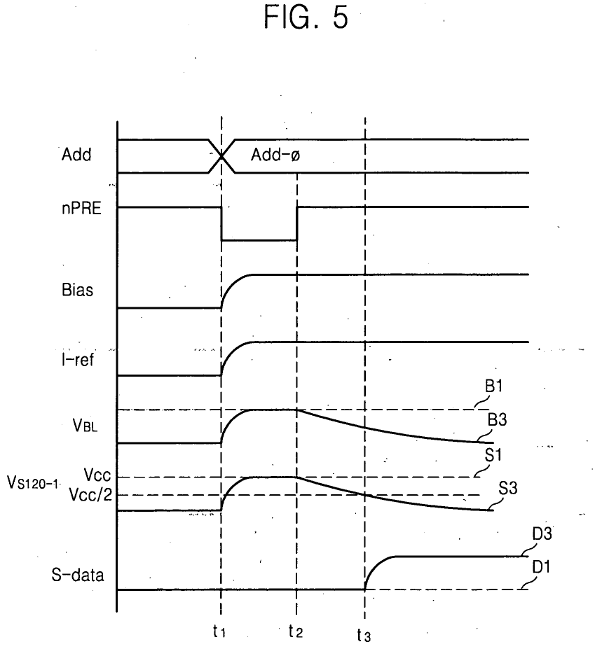

FIG. 5 is a timing diagram of a sense amplifier with a compensation current supply circuit according to some exemplary embodiments of the present invention. Referring to FIGS. 2 through 6, an address Add is input and a bias control signal Bias transits to a logical high level from a logical low level at time t1. The precharging circuit 230 supplies precharge current I_pre to the detection node S110 and each of the main detection nodes S120-1 through S120-n to precharge them to a predetermined precharge voltage until time t2, in response to a precharge control signal nPRE activated to a logical low level at the t1.

A voltage V_{S120-1} of each of the detection node S110 and the main detection nodes S120-1, . . . , S120-n is increased to a predetermined precharge voltage, e.g., a supply voltage or a voltage lower than the supply voltage. Thus, a voltage V_{BL}, of each of the monitoring bit line 110 connected to the detection node S110 and the bit lines 120-1 through 120-n connected to the main detection nodes S120-1 through S120-n, is increased to a predetermined level B1.

For example, when the corresponding nodes S110, S120-1, . . . , S120-n of the sense amplifier 100 are connected to the corresponding bit lines 101-1, 101-2, 101-3, 101-4, 103-1, 103-2, 103-3, 103-4, . . . , 10n-1, 10n-2, 10n-3, and 10n-4 of the main memory cell array 300, respectively, the voltage V_{BL} of each of the monitoring bit lines 101-1, 101-2, 101-3, and 101-4 and the bit lines 103-1, 103-2, 103-3, 103-4, . . . , 10n-1, 10n-2, 10n-3, and 10n-4, is increased to the predetermined level B1, based on a bias control signal Bias and selection signals output from the column decoder 60.

When precharging is completed at time t2, i.e., when a sensing amplification operation starts, the buffers 150-1 through 150-n connected to the corresponding main detection nodes S120-1, . . . , S120-n sense and buffer the voltages of the main detection nodes S120-1, . . . , S120-n, respectively.

The data outputting circuit 70 of the semiconductor device 50 includes a plurality of latch circuits (not shown). Each of the latch circuits latch whether the state of each of the second floating gate transistors M2 and M3 is in the “on” state or the “off” state based on the buffered result. For example, at time t3, when the voltage V_{S120-1} of a detection node, e.g., the detection node S120-1, which is selected from among the main detection nodes S120-1 through S120-n, is lower than a predetermined reference voltage Vcc/2 (see S3 of FIG. 5), each of the latch circuits perceives that the selected memory cell is in the “on” state and latches a signal of a logical “high” level (or ‘1’) (see D3 of FIG. 5).

However, at time t3, when the voltage V_{S120-1} of a detection node, e.g., the detection node S120-1, which is selected from among the main detection nodes S120-1 through S120-n, is higher than the predetermined reference voltage Vcc/2 (see S1 of FIG. 5), each of the latch circuits perceives that the selected memory cell is in the “off” state and latches a signal of a logical “low” level (or ‘0’) (see D1 of FIG. 5).

At time t3, if at least one memory cell connected to one of the bit lines 103-1 through 103-4, which are connected to the selected detection node, e.g., the detection node S120-1, is in the “on” state, the voltage V_{BL} of the detection node S120-1 is lowered as indicated by B3 of FIG. 5. If the at least one memory cell connected to one of the bit lines 103-1 through 10n-4 is in the “off” state, the voltage V_{BL} of the detection node S120-1 is maintained at a constant level, as indicated by B1 of FIG. 5.

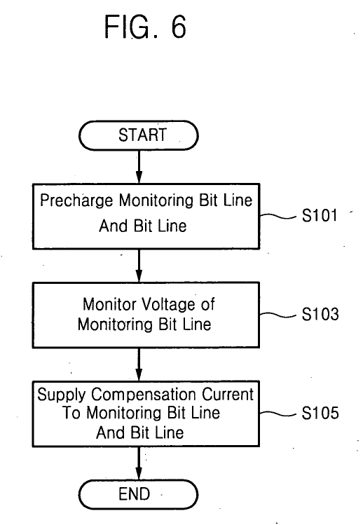

FIG. 6 is a flowchart illustrating a method of compensating for a voltage drop of a bit line according to some exemplary embodiments of the present invention.

Referring to FIGS. 3 to 6, during a precharging operation, the precharging circuit 230 supplies the current I_Pre to the detection node S110 and the main detection nodes S120-1 through S120-n to precharge them to a precharge voltage, in response to the precharge control signal nPRE (Step S101). After the precharging operation, the compensation current supply circuit 240 monitors the voltage of the detection node S110 or the voltages of the monitoring bit line 110 based on the voltage of the detection node S110 (Step S103).

Next, the compensation current supply circuit 240 supplies the compensation current I_ref to the detection node S110 and the mirrored compensation current I_load to the main detection nodes S120-1 through S120-n, based on the monitoring result (Step S105).

Accordingly, the compensation current supply circuit 240 can compensate for a voltage drop of a bit line due to at least one of under precharge of the bit line and leakage current.

FIG. 6 illustrates a method of compensating for a voltage drop of at least one bit line after a precharging operation in a semiconductor device. The semiconductor device includes at least one monitoring bit line 101-1,101-2, 101-3, and 101-4 connected to each drain of the first floating gate transistors M1 or M11. At least one bit line 103-1 through 10n-4 is connected to each drain of the second floating gate transistors M2 and M3. The voltages of the monitoring bit lines 103-1 through 10n-4 are monitored (Step S103). Predetermined compensation currents I_ref and I_load are supplied to the monitoring bit lines 101-1, 101-2, 101-3, and 101-4 and the bit lines 103-1 through 10n-4, based on the monitoring result (Step S105).

As described above, a semiconductor device according to an exemplary embodiment of the present invention has a sense amplifier for compensating for a voltage drop of a bit line and utilizes a method of compensating for a voltage drop of a bit line. Accordingly, under precharge occurring in the bit line during a precharging operation may be compensated for. Therefore, a read operation of the semiconductor device can be stably performed.

Also, a semiconductor device according to another exemplary embodiment of the present invention has a sense amplifier for compensating for a voltage drop of a bit line and utilizes a method of compensating for a voltage drop of a bit line. Accordingly, leakage current generated in a memory cell may be compensated for thereby preventing unnecessary compensation current from being supplied.

While exemplary embodiments of the invention have been particularly shown and described herein, it will be understood by those skilled in the art that various changes in form and details may be made without departing from the spirit and scope of the invention.

What is claimed is:

1. A semiconductor device comprising:
a first monitoring bit line connected to at least one first memory cell having a source, a drain, a floating gate, a control gate, and a substrate;
a first main memory bit line connected to at least one second memory cell having a source, a drain, a floating gate, a control gate, and a substrate;
a precharging circuit precharging a second monitoring bit line and a second main memory bit line to a predetermined voltage in response to a precharge control signal;
a compensation current supply circuit sensing a voltage of the second monitoring bit line, and supplying a predetermined current to the second monitoring bit line and the second main memory bit line, based on a result of the sensing of the voltage of the second monitoring bit line;
a buffer buffering current flowing through the second main memory bit line, based on a state of the at least one second memory cell connected to the first main memory bit line; and
a switching circuit controlling a connection of the first monitoring bit line to the second monitoring bit line and a connection of the first main memory bit line to the second main memory bit line, in response to at least one corresponding control signal.

2. The semiconductor device of claim 1, wherein the drain of the at least one first memory cell is connected to the first monitoring bit line, and the source of the at least one first memory cell is in a floating state,
the drain of the at least one second memory cell is connected to the first main memory bit line, and the source of the at least one second memory cell is connected to ground, and
the control gate of the at least one first memory cell and the control gate of the at least one second memory cell are respectively connected to corresponding word lines.

3. The semiconductor device of claim 1, wherein the drain of the at least one first memory cell is connected to the first monitoring bit line, and the source and the control gate of the at least one first memory cell are connected to ground, and
the drain of the at least one second memory cell is connected to the first main memory bit line, the source of the at least one second memory cell is connected to ground, and the control gate of the at least one second memory cell is connected to a word line.

4. The semiconductor device of claim 1, wherein the at least one first memory cell is in a program state.

5. The semiconductor device of claim 1, wherein the compensation current supply circuit is a current mirror sensing the voltage of the second monitoring bit line, and mirroring the predetermined current flowing through the second monitoring bit line to the second main memory bit line based on the result of the sensing of the voltage of the second monitoring bit line.

6. A semiconductor device comprising:
at least one monitoring bit line connected to a drain of each of a plurality of first floating gate transistors;
at least one main memory bit line connected to a drain of each of a plurality of second floating gate transistors; and
a compensation current supply circuit monitoring a voltage of the at least one monitoring bit line after a precharging operation, and supplying a predetermined compensation current to the at least one monitoring bit line and the at least one main memory bit line based on a monitoring result.

7. The semiconductor device of claim 6, wherein a source of each of the first floating gate transistors is in a floating state, and
a control gate of each of the first floating gate transistors and a control gate of each of the second floating gate transistors are connected to corresponding word lines of a plurality of word lines.

8. The semiconductor device of claim 6, wherein a control gate and source of each of the first floating gate transistors are connected to ground, and
a control gate of each of the second floating gate transistors is connected to a corresponding word line of a plurality of word lines, and a source of each of the second floating gate transistors is connected to ground.

9. The semiconductor device of claim 6, wherein each of the first floating gate transistors is in a program state.

10. The semiconductor device of claim 6, wherein the compensation current supply circuit is formed as a current mirror, and
a plurality of output terminals of the current mirror are respectively connected to the at least one monitoring bit line and the at least one main memory bit line, and the compensation current mirrored by the current mirror is supplied to the at least one main memory bit line.

11. The semiconductor device of claim 6, wherein the first floating gate transistors and the second floating gate transistors are embodied in a main memory cell array, and
a total number of the first floating gate transistors is equal to a total number of the second floating gate transistors.

12. A semiconductor device comprising:
at least one monitoring bit line;
a plurality of main memory bit lines;
a detection node;
a plurality of main detection nodes;
a precharging circuit supplying a predetermined precharge voltage to the detection node and the main detection nodes in response to a precharge control signal;
at least one first transistor connecting the detection node and the at least one monitoring bit line in response to at least one first control signal;
at least one second transistor respectively connecting the main memory bit lines and the main detection nodes in response to at least one second control signal;
a compensation current supply circuit supplying compensation current to the detection node and the main detection nodes, based on a voltage of the detection node; and
a plurality of buffers, each sensing and buffering a voltage of a corresponding node of the main detection nodes,
wherein the at least one monitoring bit line is connected to each drain of a plurality of first floating gate transistors,
and the main memory bit lines are respectively connected to drains of a plurality of second floating gate transistors.

13. The semiconductor device of claim 12, wherein a source of each of the first floating gate transistors is in a floating state, and
a control gate of each of the first floating gate transistors and a control gate of each of the second floating gate transistors are connected to corresponding word line of a plurality of word lines.

14. The semiconductor device of claim 12, wherein a control gate and a source of each of the first floating gate transistors are connected to ground, and
a control gate of each of the second floating gate transistors is connected to a corresponding word line of a plurality of word lines, and a source of each of the second floating gate transistors is connected to ground.

15. The semiconductor device of claim 12, wherein each state of the first floating gate transistors is in a program state.

16. The semiconductor device of claim 12, wherein the compensation current supply circuit is formed as a current mirror,
a plurality of output terminals of the current mirror are respectively connected to the main detection nodes, and the compensation current mirrored by the current mirror is supplied to the main detection nodes.

17. The semiconductor device of claim 12, wherein the first floating gate transistors and the second floating gate transistors are embodied in a main memory cell array, and
a total number of the first floating gate transistors is equal to a total number of the second floating gate transistors.

18. A method of compensating for a voltage drop of at least one main memory bit line after a precharging operation in a semiconductor device having at least one monitoring bit line connected to each drain of a plurality of first floating gate transistors and the at least one main memory bit line connected to each drain of a plurality of second floating gate transistors, the method comprising:
monitoring a voltage of the at least one monitoring bit line; and
supplying a predetermined compensation current to the at least one monitoring bit line and the at least one main memory bit line based on a monitoring result.

19. The method of claim 18, further comprising maintaining each of the first floating gate transistors in an off state.
